(19) United States
(12) Patent Application Publication
(10) Pub. No.: US 2006/0084268 A1
(43) Pub. Date: Apr. 20, 2006

(54) Method for production of charge-trapping memory cells

(76) Inventor: Martin Verhoeven, Radebeul (DE)

Correspondence Address: SLATER & MATSIL LLP, 17950 PRESTON ROAD, SUITE 1000, DALLAS, TX, 75252, US

(21) Appl. No.: 10/967,014

(22) Filed: Oct. 15, 2004

(51) Int. Cl. H01L 21/302; H01L 21/461

(52) U.S. Cl. 438/689; 438/706; 438/717

(57) ABSTRACT

An oxide layer, a nitride layer, and a layer of amorphous silicon are applied to a surface of a semiconductor substrate. A resist mask is applied and implantations are performed to form doped regions of source and drain and doped regions within the amorphous silicon layer. The resist mask and undoped parts of the amorphous silicon are removed to form a silicon mask. The silicon mask is applied to etch back the nitride layer. After a removal of the silicon mask, the nitride is oxidized to form an oxide-nitride-oxide layer sequence, which is laterally restricted to the area above the source/drain regions.

### TECHNICAL FIELD

The invention concerns the fabrication of charge-trapping memory cells comprising an oxide-nitride-oxide memory layer sequence and being intended to store two bits of information.

### BACKGROUND

Non-volatile memory cells that are electrically programmable and erasable can be realized as charge-trapping memory cells, which comprise a memory layer sequence of dielectric materials with a memory layer between confinement layers of dielectric material having a larger energy band gap than the memory layer. The memory layer sequence is arranged between a channel region within a semiconductor body and a gate electrode provided to control the channel by means of an applied electric voltage. Charge carriers moving from source to a drain through the channel region are accelerated and gain enough energy to be able to penetrate the lower confinement layer and to be trapped within the memory layer. The trapped charge carriers change the threshold voltage of the cell transistor structure. Different programming states can be read by applying the appropriate reading voltages. Examples of charge-trapping memory cells are the SONOS memory cells, in which each confinement layer is an oxide and the memory layer is a nitride of the semiconductor material, usually silicon.

Typical applications of memory products require a steady miniaturization of the memory cells. A reduction of the area that is required by an individual memory cell can be obtained by shrinking the cell structure or by an increase of the number of bits that can be stored within one memory cell transistor structure.

A publication by B. Eitan et al., “NROM: a Novel Localized Trapping, 2-Bit Nonvolatile Memory Cell” in IEEE Electron Device Letters, volume 21, pages 543 to 545 (2000), which publication is incorporated herein by reference, describes a charge-trapping memory cell with a memory layer sequence of oxide, nitride and oxide which is especially adapted to be operated with a reading voltage that is reverse to the programming voltage (reverse read). The oxide-nitride-oxide layer sequence is especially designed to avoid the direct tunneling regime and to guarantee the vertical retention of the trapped charge carriers. The oxide layers are specified to have a thickness of more than 5 nm. Two bits of information can be stored in every memory cell.

In order to provide a better two-bit separation in charge-trapping memory cells, several different structures of an arrangement of separate memory layers of dielectric material or floating gate electrodes at both sides of the gate electrode above the source and drain junctions at the channel ends have been proposed. During the write operation to program the memory cell, channel-hot electrons are injected predominantly in the ONO area just above the pn junction at the drain. A reversal of the electric voltage between source and drain enables the storage of a second bit at the other channel end.

In the course of further miniaturization of the memory cell, the problem of a precise arrangement and localization of the memory layer with respect to the gate electrode and the regions of source and drain is of increasing importance. The further shrinking of the cell dimensions will imply a greater difficulty to separate the two bits that are stored in the same memory cell. This derives from the fact that electrons are to some extent injected also in the area between the regions of source and drain. Therefore, memory layer structures have been proposed, in which the memory layer is interrupted above the channel region.

### SUMMARY OF THE INVENTION

In one aspect, the present invention provides an improved fabrication method for charge-trapping memory cells that are intended for two-bit storage.

In a further aspect, the invention provides a method for the fabrication of charge-trapping memory cells with improved two-bit separation that is suitable for a shrinkage of the device structures.

In still a further aspect, this invention provides the aforementioned methods with standard process steps of semiconductor technology.

The method according to this invention comprises the steps of applying an oxide layer, a nitride layer, and a layer of amorphous silicon onto a main surface of a semiconductor substrate, applying a resist mask with openings and performing an implantation of doping atoms to form doped regions of source and drain. By a further implantation step, the layer of amorphous silicon is provided with a dopant in areas located above the regions of source and drain. The resist mask and parts of the silicon layer that have not been implanted are subsequently removed and the remaining parts of the silicon layer are used as a silicon mask in further process steps. The nitride layer beneath the layer of amorphous silicon is partly etched back in the areas that are not covered by the silicon. Then, the silicon layer is removed and the nitride is oxidized until only parts of the nitride layer remain within areas above the source and drain regions. In this manner, oxide-nitride-oxide memory layer sequences are formed that are laterally restricted to the areas of source and drain and formed in self-aligned fashion with respect to the source and drain regions.

A preferred alternative comprises a further method step, by which the resist mask is laterally reduced or trimmed between the implantation steps to form the source and drain regions and to form the doped regions within the amorphous silicon layer so that the produced ONO layer slightly extends over the lateral boundaries of the source and drain regions.

These and other features and advantages of the invention will become apparent from the following brief description of the drawings, detailed description and appended claims and drawings.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1a shows a cross-section of a first intermediate product of an example of the inventive method after the application of the amorphous silicon layer and resist mask;

FIG. 1b shows the cross-section according to FIG. 1a after the implantation steps;

FIG. 1c shows the cross-section according to FIG. 1b after the removal of the resist mask and non-implanted parts of the silicon layer;

FIG. 1d shows the cross-section of FIG. 1c after the etching of the nitride layer;

FIG. 1e shows the cross-section according to FIG. 1d after an oxidation step;

FIG. 1f shows the cross-section of FIG. 1e after the application of the gate conductor;

FIG. 2a shows a cross-section according to FIG. 1a;

FIG. 2b shows the cross-section according to FIG. 2a after the implantation of the source and drain regions;

FIG. 2c shows the cross-section of FIG. 2b after a pull-back step to widen the openings in the resist mask;

FIG. 2d shows the cross-section according to FIG. 2c after a further implantation step;

FIG. 2e shows the cross-section of FIG. 2d after the removal of the resist mask and non-implanted regions of the silicon layer;

FIG. 2f shows the cross-section of FIG. 2e after an etching of the nitride layer;

FIG. 2g shows the cross-section according to FIG. 2f after an oxidation step; and

FIG. 2h shows the cross-section according to FIG. 2g after the application of the gate conductor.

### LIST OF REFERENCE NUMERALS

1. substrate

2. oxide layer

3. nitride layer

4. layer of amorphous silicon

5. resist mask

6. source/drain region

7. silicon mask

8. second oxide layer

9. gate conductor

### DETAILED DESCRIPTION OF ILLUSTRATIVE EMBODIMENTS

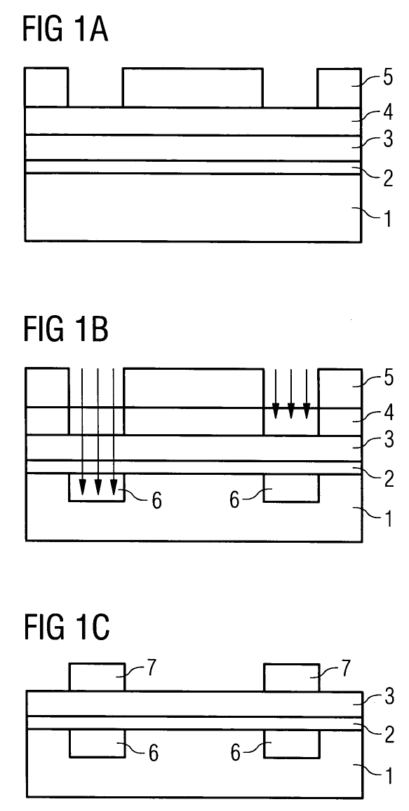

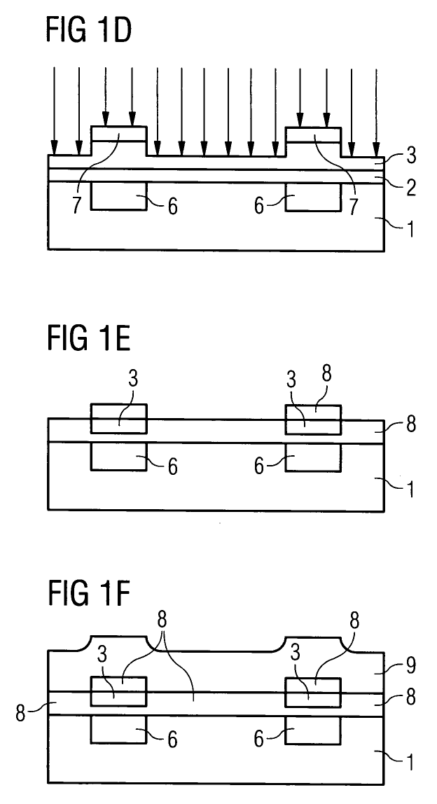

The general method according to the preferred embodiment of this invention is first described with reference to FIGS. 1a to 1f, which show different intermediate products of an example of the method. According to the cross-section shown in FIG. 1a, a substrate 1 of semiconductor material, preferably silicon, is provided with a layer sequence comprising an oxide layer 2 that is applied on a main surface of the substrate, a nitride layer 3 and a layer of amorphous silicon 4. A resist mask 5 is applied, which has openings in the areas of the regions of source and drain to be formed by a subsequent implantation step.

FIG. 1b shows the cross-section of the intermediate product according to FIG. 1a after the performance of two implantation steps. This is indicated in FIG. 1b by the arrows pointing downwards into the regions in which a dopant is implanted to form doped regions. A deep implantation forms the regions of source and drain 6. A shallow implantation forms doped regions within the layer of amorphous silicon 4 in areas that are located above the source/drain regions 6. The sequence of implantation steps is not fixed; it is preferred to perform the deep implantation first and the shallow implantation afterwards. However, the reverse order is also possible.

FIG. 1c shows a further intermediate product in a cross-section according to FIG. 1b after the removal of the resist mask 5 and of those parts of the amorphous silicon layer which have not been implanted. The remaining parts of the silicon layer 4, which are doped, form a silicon mask 7 above the areas of the source/drain regions 6.

FIG. 1d shows the cross-section according to FIG. 1c after a subsequent etching step, indicated by the arrows in FIG. 1d, by which the nitride layer 3 is partly removed in a vertical direction. The silicon mask 7 is applied to restrict the etching to areas between the source/drain regions 6. Above the source/drain regions 6, the nitride layer 3 remains in its original thickness.

FIG. 1e shows a further intermediate product after the removal of the silicon mask 7 and an oxidation step to form a second oxide layer 8. This second oxide layer 8 comprises the original oxide layer 2 and parts of the nitride layer 3 which are completely converted into oxide, thus forming the second oxide layer 8. The thickness of the nitride layer 3 and the depth of the etching step shown in FIG. 1d are adapted so that the oxidation step forms a thorough oxide layer 8 in the areas between the source/drain regions 6, while thin remaining layer parts of the nitride layer 3 are left above the source/drain regions 6. In this way, an oxide-nitride-oxide layer sequence is formed above the source/drain regions 6 in a self-aligned manner with respect to the source/drain regions 6. Thus, the memory layer sequence can be arranged exactly above the source and drain regions and completely interrupted above the channel region provided between source and drain.

FIG. 1f shows the cross-section according to FIG. 1e after the application of a gate conductor 9 to form gate electrodes above the channel regions and wordlines to connect the gate electrodes along rows of memory cell arrays.

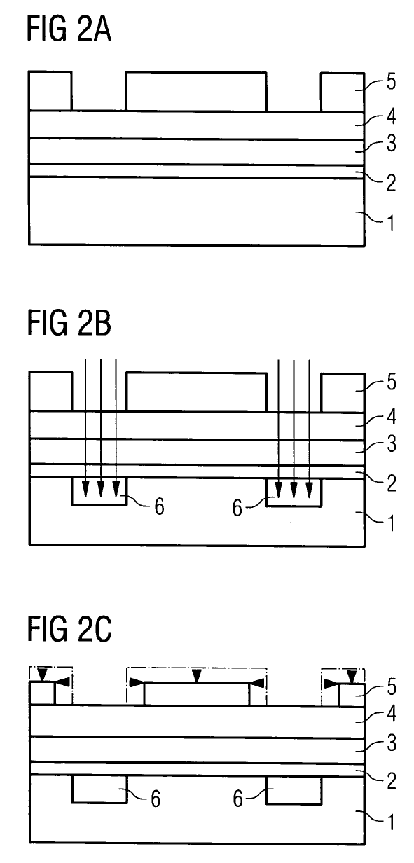

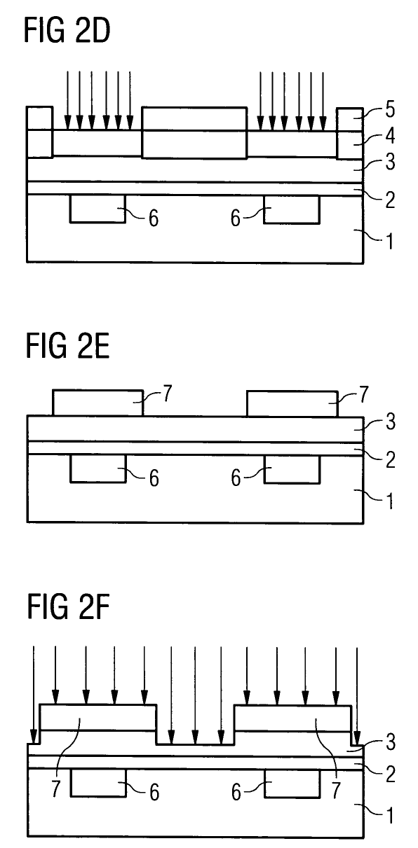

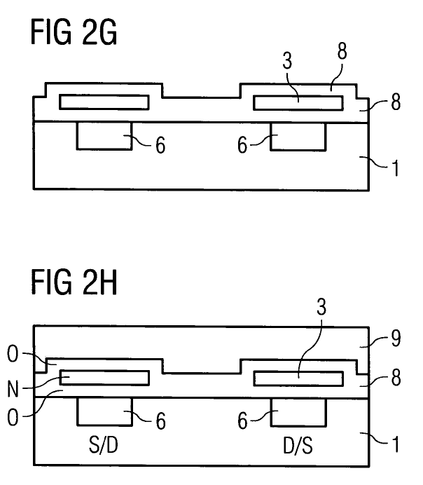

FIGS. 2a to 2h show cross-sections of intermediate products of an alternate embodiment of the inventive method, which is especially preferred. It may be desired to have memory layer sequences above the pn junctions of the source and drain regions adjacent to the channel. This can be accomplished by the following method, which comprises an additional method step between the two implantation procedures.

FIG. 2a shows the cross-section according to FIG. 1a, showing that the point of departure is the same as in the general method.

FIG. 2b shows the subsequent implantation step to form the source/drain regions 6. This alternative embodiment comprises a further method step after the deep implantation indicated in FIG. 2b.

FIG. 2c shows this further method step, which is a pull-back step to widen the openings of the resist mask 5. This is indicated in FIG. 2c by the arrows in the form of triangles and the broken lines representing the original contours of the resist mask 5. The larger openings, which are produced in this way, define the area of the later oxide-nitride-oxide layer sequence, which is intended as storage means.

FIG. 2d shows the cross-section according to FIG. 2c for the further implantation step, by which those regions of the amorphous silicon layer 4 are doped which are left free by the widened openings of the resist mask 5. These doped regions are self-aligned to the source/drain regions 6 at least as far as the pull-back step according to FIG. 2c can be controlled, but slightly extend over the lateral boundaries of the source/drain regions.

FIG. 2e shows the cross-section of FIG. 2d after the removal of the resist mask 5 and the undoped regions of the layer of amorphous silicon 4. In this way, a silicon mask 7 is formed, which has slightly smaller openings as compared to the silicon mask 7, which is applied in the first embodiment of the method described above.

FIG. 2f shows the cross-section according to FIG. 2e for the subsequent etching step, by which those parts of the nitride layer 3 that are not covered by the silicon mask 7 are removed to a certain predefined depth.

FIG. 2g shows the cross-section according to FIG. 2f after the removal of the silicon mask 7 and the performance of an oxidation step to form the second oxide layer 8 according to the first embodiment of the method. A comparison between FIGS. 2g and 1e shows the difference in the lateral extension of the formed ONO layer.

FIG. 2h shows the cross-section of the product that is obtained after the application of the gate conductor 9. Further standard process steps, which are known per se can follow to complete this device.

Although the present invention and its advantages have been described in detail, it should be understood that various changes, substitutions and alterations can be made herein without departing from the spirit and scope of the invention as defined by the appended claims.

What is claimed is:

1. A method of manufacturing a semiconductor device, the method comprising:
providing a semiconductor body;
forming an oxide layer over said semiconductor body;
forming a nitride layer over said oxide layer;
etching back said nitride layer in areas overlying the semiconductor body; and
performing an oxidation to convert portions of said nitride layer into oxide, the oxidation leaving parts of said nitride layer located in the areas overlying the semiconductor body.

2. The method of claim 1 wherein etching back said nitride layer comprises:
forming a mask overlying the nitride layer;
using said mask to etch back said nitride layer; and
removing said mask.

3. The method of claim 2 wherein the mask comprises silicon:

4. The method of claim 3 wherein forming a mask comprises:
forming a silicon layer over the nitride layer;
doping portions of the silicon layer overlying the areas of the nitride layer; and
removing portions of the silicon layer that were not doped in the doping step.

5. The method of claim 4 wherein forming a silicon layer comprises forming an amorphous silicon layer.

6. The method of claim 1 wherein providing a semiconductor body comprises providing a semiconductor substrate.

7. The method of claim 1 and further comprising implanting at least two doped regions in the semiconductor body such that the areas of the nitride layer overlie the doped regions.

8. The method of claim 7 wherein implanting at least two doped regions comprises:
forming a resist mask over the semiconductor body; and
implanting dopants into portions of the semiconductor body that are exposed by the resist mask.

9. The method of claim 8 wherein etching back said nitride layer comprises:
forming a silicon mask overlying the at least two doped regions;
using the silicon mask to etch back the nitride layer; and
removing the mask.

10. The method of claim 9 wherein forming a mask comprises:
forming a silicon layer over the nitride layer;
doping portions of the silicon layer overlying the at least two doped regions; and
removing portions of the silicon layer that were not doped in the doping step.

11. The method of claim 10 wherein doping portions of the silicon layer comprises performing an implantation step and wherein implanting dopants into a portion of the semiconductor body comprises performing a different implantation step.

12. The method of claim 11 wherein the different implantation step is performed before the implantation step.

13. The method of claim 1 and further comprising forming a conductive layer over the semiconductor body after performing the oxidation.

14. A method of manufacturing a semiconductor device, the method comprising:
providing a semiconductor body;
forming an oxide layer over the semiconductor body;
forming a nitride layer over the oxide layer;
etching back portions of the nitride layer such that the nitride layer includes stepped regions and adjacent etched regions, the etched regions being thinner than the stepped regions; and
oxidizing the etched regions of the nitride layer and also upper portions of the stepped regions of the nitride layer such that the etched regions and the upper portions of the stepped regions are converted into oxide.

15. The method of claim 13 wherein lower portions of the stepped portions of the nitride layer are not oxidized.

16. The method of claim 13 and further comprising forming doped regions in the semiconductor body beneath the stepped regions of the nitride layer.

17. The method of claim 15 and further comprising forming a conductive layer overlying the stepped portions of the nitride layer.

18. A method for producing charge-trapping memory cells with separate memory layers for two-bit separation, the method comprising:
providing a semiconductor substrate;
applying an oxide layer on said substrate;
applying a nitride layer on said oxide layer;
applying a layer of amorphous silicon on said nitride layer;
applying a resist mask with openings on said layer of amorphous silicon;
using said resist mask in a subsequent implantation to form doped regions of source and drain and to provide said layer of amorphous silicon with doped regions that are located above said doped regions of source and drain;
removing said resist mask;
removing part of said layer of amorphous silicon that has not been provided with a doping, to form a silicon mask;
using said silicon mask to etch back said nitride layer;
removing said silicon mask;
performing an oxidation to convert all of said nitride layer into oxide, except for parts of said nitride layer that are located in areas above said doped regions of source and drain, thus forming an oxide-nitride-oxide layer sequence above these areas; and
applying a gate conductor provided as gate-electrode and wordline.

19. The method according to claim 18, and further comprising widening the openings of said resist mask after the formation of said doped regions of source and drain and before the formation of said doped regions in said layer of amorphous silicon.

20. The method according to claim 19, and further comprising providing the layers within said oxide-nitride-oxide layer sequence with thicknesses that are suitable for a storage by charge trapping.

21. The method according to claim 18, and further comprising providing the layers within said oxide-nitride-oxide layer sequence with thicknesses that are suitable for a storage by charge trapping.
